(19) United States
(12) Patent Application Publication
(10) Pub. No.: US 2024/0329157 A1
(43) Pub. Date: Oct. 3, 2024

(54) BATTERY MONITORING DEVICE

(71) Applicant: LAPIS Technology Co., Ltd., Yokohama (JP)

(72) Inventor: Ryo MATSUMOTO, Yokohama (JP)

(73) Assignee: LAPIS Technology Co., Ltd., Yokohama (JP)

(21) Appl. No.: 18/607,592

(22) Filed: Mar. 18, 2024

(30) Foreign Application Priority Data
Mar. 30, 2023 (JP) 2023-055527

(51) Int. Cl. G01R 31/66

(52) U.S. Cl. CPC G01R 31/66

(57) ABSTRACT

Disconnection detection for a plurality of connection lines respectively connected to a plurality of battery cells is performed in a short time. A battery monitoring device has a function of detecting disconnection for each of a plurality of connection lines respectively connected to the battery cells of a battery pack in which the plurality of battery cells is connected in series. The battery monitoring device includes a plurality of internal wirings respectively connected to the plurality of connection lines, a plurality of transistors provided corresponding to the plurality of internal wirings and turned on according to a potential difference between a corresponding internal wiring and an internal wiring adjacent to the corresponding internal wiring, and a determination circuit that performs a determination process of determining the presence or absence of disconnection of each of the plurality of connection lines based on output voltages of the plurality of transistors.

### CROSS-REFERENCE TO RELATED APPLICATION

This application claims the priority benefits of Japanese application no. 2023-055527, filed on Mar. 30, 2023. The entirety of the above-mentioned patent application is hereby incorporated by reference herein and made a part of this specification.

### BACKGROUND

### Technical Field

The disclosed technology relates to a battery monitoring device.

### Description of Related Art

The following technology is known as a technology related to disconnection detection for a connection line connected to an electrode of each battery cell of a battery pack in which a plurality of battery cells is connected in series. Patent Document 1 (Japanese Patent Laid-Open No. 2009-288034) discloses a technology in which, in a battery pack monitoring device that detects the presence or absence of disconnection of a wiring drawn out from a battery pack in which a plurality of single cells is connected in series, an auxiliary current path having a set resistance value is connected in parallel to each of the single cells, and the presence or absence of disconnection of the wiring is detected on the basis of a voltage detected when a switch device for the auxiliary current path is in a closed state.

Patent Document 2 (Japanese Patent Laid-Open No. 2015-100199) discloses a technology in which detection lines connectable to connection points of adjacent battery cells and end parts of a battery pack, a voltage detection circuit that detects a unit voltage between adjacent detection lines as a cell voltage of a corresponding battery cell, a capacitor connected between a detection line connected to an upper end part of the battery pack and a different detection line, an intercell switch of which both ends are connected to the adjacent detection lines, a diode that is connected in parallel to the intercell switch and causes a current to flow, and a reversing switch connected between the detection lines are provided, and when the intercell switch is turned on for a predetermined period and then turned off, and the reversing switch is turned on, disconnection of the detection line connected to the upper end part of the battery pack is determined on the basis of a polarity of the highest cell voltage.

In a battery monitoring device that monitors a state of each battery cell in a battery pack in which a plurality of battery cells is connected in series, the following configuration may be used to detect disconnection of a connection line connected to the electrode of each battery cell. For example, a battery monitoring device including a plurality of switches provided to correspond to respective connection lines, a plurality of current sources provided to correspond to the respective connection lines and connected to the corresponding connection lines, and a determination circuit is assumed. In this battery monitoring device, one of the plurality of battery cells is selected by selectively turning on one of the plurality of switches. The selected battery cell is connected to the determination circuit via the connection line and the switch that is turned on, and a voltage between positive and negative electrodes of the battery cell (hereinafter, referred to as a cell voltage) is measured by the determination circuit. The determination circuit determines whether or not there is disconnection in the corresponding connection line on the basis of a difference between a cell voltage when the current source is turned on and a cell voltage when the current source is turned off for the battery cell that is a measurement target.

However, according to the above disconnection detection method, it is necessary to sequentially select the battery cells by sequentially turning on the plurality of switches, and measure cell voltages by switching the current sources between on and off for the selected battery cells. Therefore, it takes a relatively long time to detect disconnection for all connection lines.

The disclosed technology is capable of detecting disconnection in a short time for a plurality of connection lines respectively connected to a plurality of battery cells.

### SUMMARY

According to the disclosed technology, there is provided a battery monitoring device having a function of detecting disconnection of each of a plurality of connection lines respectively connected to a plurality of battery cells of a battery pack in which the plurality of battery cells is connected in series, the battery monitoring device including a plurality of internal wirings respectively connected to the plurality of connection lines; a plurality of transistors provided to correspond to the plurality of internal wirings and turned on according to a potential difference between a corresponding internal wiring and an internal wiring adjacent to the corresponding internal wiring; and a determination circuit that performs a determination process of determining presence or absence of disconnection of each of the plurality of connection lines based on output voltages of the plurality of transistors.

### BRIEF DESCRIPTION OF THE DRAWINGS

FIG. 1 is a diagram illustrating an example of a configuration of a battery monitoring device according to an embodiment of the disclosed technology.

FIG. 2 is a diagram illustrating an example of a configuration of a battery monitoring device according to a comparative example.

FIG. 3 is a diagram illustrating an example of a flow of each process performed when a determination circuit of the battery monitoring device according to the embodiment of the disclosed technology and a determination circuit of the battery monitoring device according to the comparative example detect disconnection of a connection line.

### DESCRIPTION OF THE EMBODIMENTS

Hereinafter, an example of an embodiment of the disclosed technology will be described with reference to the drawings. In each drawing, the same or equivalent constituents and preparations are given the same reference numerals, and redundant description will be omitted.

According to the disclosed technology, it is possible to detect disconnection in a short time for a plurality of connection lines respectively connected to a plurality of battery cells.

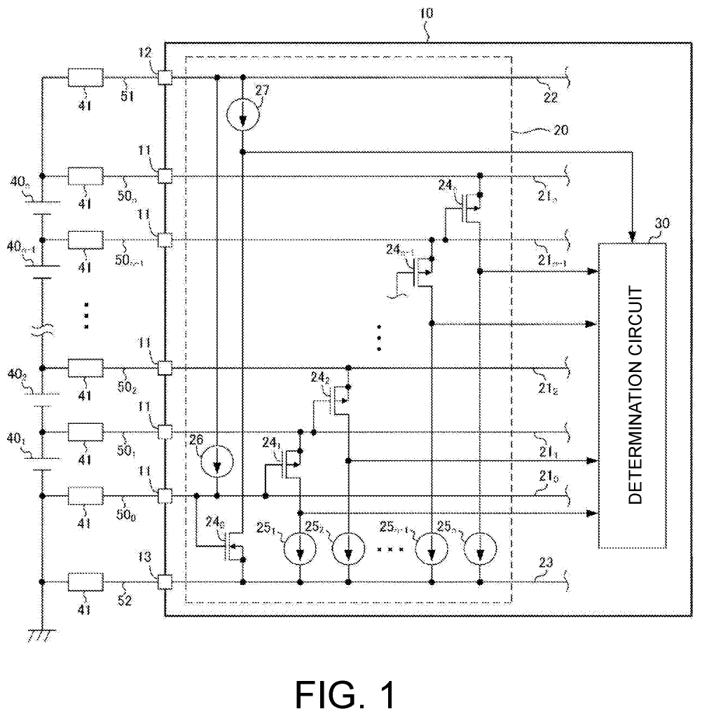

FIG. 1 is a diagram illustrating an example of a configuration of a battery monitoring device 10 according to an embodiment of the disclosed technology. The battery monitoring device 10 has a function of monitoring a state of each battery cell of a battery pack including a plurality of battery cells 40₁, 40₂, . . . , 40ₙ₋₁, and 40ₙ connected in series. In a case where the plurality of battery cells 40₁, 40₂, . . . , 40ₙ₋₁, and 40ₙ is not distinguished or is collectively referred to, the battery cells will be referred to as battery cells 40.

The battery monitoring device 10 may have a function of measuring a voltage between a positive electrode and a negative electrode of each battery cell 40 (hereinafter, referred to as a cell voltage). The battery monitoring device 10 may include a cell selection switch and an analog-to-digital converter to measure a cell voltage. The cell selection switch selectively connects one of the plurality of battery cells 40 to the analog-to-digital converter. The analog-to-digital converter outputs a digital value corresponding to the cell voltage of the battery cell selected by the cell selection switch.

The battery monitoring device 10 has a function of detecting disconnection in a plurality of connection lines 50₀, 50₁, 50₂, . . . , 50ₙ₋₁, and 50ₙ connected to respective electrodes of the battery cells 40. In a case where the plurality of connection lines 50₀, 50₁, 50₂, . . . , 50ₙ₋₁, and 50ₙ is not distinguished or is collectively referred to, the connection lines will be referred to as connection lines 50. FIG. 1 illustrates functional portions related to disconnection detection for the connection line 50 in the battery monitoring device 10.

The battery monitoring device 10 includes an integrated circuit provided on a semiconductor substrate. The battery monitoring device 10 has a plurality of input terminals 11 provided to correspond to a plurality of connection lines 50. Each of the input terminals 11 is connected to the corresponding battery cell 40 via the corresponding connection line 50. The connection line 50 is a conductive path that connects the battery cell 40 to the input terminal 11. A low-pass filter 41 is provided on each connection line 50 to suppress noise.

The battery monitoring device 10 has a plurality of internal wirings 21₀, 21₁, 21₂, . . . , 21ₙ₋₁, and 21ₙ connected to the respective connection lines 50. In a case where the plurality of internal wirings 21₀, 21₁, 21₂, . . . , 21ₙ₋₁, and 21ₙ is not distinguished or is collectively referred to, the connection lines will be referred to as internal wirings 21. The battery monitoring device 10 has a power supply wiring 22 and a ground wiring 23. The power supply wiring 22 is connected to the positive electrode of the battery cell 40 having the highest potential via a power supply terminal 12 and the power supply connection line 51. A connection line 50ₙ connected to the positive electrode of the battery cell 40 having the highest potential is connected to a power supply connection line 51 outside the battery monitoring device 10. Therefore, unless disconnection occurs in the connection line 50ₙ, the internal wiring 21ₙ has the same potential as a potential of the power supply wiring 22.

The ground wiring 23 is connected to the negative electrode of the battery cell 401 having the lowest potential via a ground terminal 13 and a ground connection line 52, and is also connected to the ground potential. The connection line 50₀ is connected to the ground connection line 52 outside the battery monitoring device 10. Therefore, unless a disconnection occurs in the connection line 50₀, the internal wiring 21₀ has the same potential as a potential of the ground wiring 23 (that is, the ground potential). The low-pass filter 41 is provided on each of the power supply connection line 51 and the ground connection line 52.

The battery monitoring device 10 includes a detection voltage output circuit 20 and a determination circuit 30 as functional portions related to disconnection detection for the connection line 50. The detection voltage output circuit 20 includes a plurality of P-channel type transistors 24₁, 24₂, . . . , 24ₙ₋₁, and 24ₙ provided to correspond to the plurality of internal wirings 21, and a plurality of current sources 25₁, 25₂, . . . , 25ₙ₋₁, and 25ₙ provided to correspond the transistors. In a case where the plurality of current sources 25₁, 25₂, . . . , 25ₙ₋₁, and 25ₙ is not distinguished or is collectively referred to, the current sources will be referred to as current sources 25. The current source 25 is an example of a “first current source” in the disclosed technology. The current source 25 is operated during a period in which a disconnection detection process on the connection line 50 is performed in the battery monitoring device 10, and stops to be operated during other periods.

Each of the transistors 24₁, 24₂, . . . , 24ₙ₋₁, and 24ₙ is turned on according to a potential difference between the corresponding internal wiring 21 and the internal wiring 21 adjacent thereto. Each of the transistors 24₁, 24₂, . . . , 24ₙ₋₁, and 24ₙ has a source connected to the corresponding internal wiring 21, a gate connected to the adjacent internal wiring 21 on the low potential side, and a drain connected to the corresponding current source 25. For example, the transistor 24₂ has a source connected to the internal wiring 21₂, a gate connected to the internal wiring 21₁, and a drain connected to the current source 25₂, and is turned on in a case where a difference (V₂−V₁) between a potential V₂ of the internal wiring 21₂ and a potential V₁ of the internal wiring 21₁ is more than a threshold voltage Vth (V₂−V₁>Vth), and is turned off in other cases. Each of the connection points between the transistors 24₁, 24₂, . . . , 24ₙ₋₁, and 24ₙ and the corresponding current source 25 is connected to the determination circuit 30. That is, a voltage generated at the drain of each of the transistors 24₁, 24₂, 24₃, . . . , 24ₙ₋₁, and 24ₙ is input to the determination circuit 30.

The detection voltage output circuit 20 includes current sources 26 and 27 and an N-channel transistor 24₀. The current source 26 is provided between the power supply wiring 22 and the internal wiring 21₀, and biases the internal wiring 21₀. The internal wiring 21₀ is an example of a “lowest potential internal wiring” in the disclosed technology. The current source 26 is an example of a second current source in the disclosed technology. The current source 26 is operated during a period in which a disconnection detection process on the connection line 50 is performed in the battery monitoring device 10, and stops to be operated during other periods.

The transistor 24₀ has a gate connected to the internal wiring 21₀, a source connected to the ground wiring 23, and a drain connected to the current source 27. The current source 27 is provided between the power supply wiring 22 and the drain of the transistor 240. The current source 27 is operated during a period in which a disconnection detection process on the connection line 50 is performed in the battery monitoring device 10, and stops to be operated during other periods. The transistor 24₀ is turned on in a case where a difference (V₀−V_{GND}) between a potential V₀ of the internal wiring 21₀ and a potential V_{GND} of the ground wiring 23 is more than the threshold voltage Vth (V₀−V_{GND})>Vth), and is turned off in other cases. A connection point between the transistor 240 and the current source 27 is connected to the determination circuit 30. That is, a voltage generated at the drain of the transistor 240 is input to the determination circuit 30. In the following description, in a case where the plurality of transistors 24₀, 24₁, 24₂, . . . , 24ₙ₋₁, and 24ₙ is not distinguished or is collectively referred to, the transistors will be referred to as transistors 24.

A level of the voltage generated at the drain of the transistor 24 changes depending on the presence or absence of disconnection of the corresponding connection line 50. A voltage generated at the drain of the transistor 24 corresponding to the connection line 50 that is not disconnected has a high level, while a voltage generated at the drain of the transistor 24 corresponding to the connection line 50 that is disconnected has a low level. That is, the voltage generated at the drain of the transistor 24 is a detection voltage indicating the presence or absence of disconnection of the corresponding connection line 50. The detection voltages generated at the respective drains of the plurality of transistors 24 are simultaneously input to the determination circuit 30.

The determination circuit 30 performs a determination process of determining whether there is disconnection of each of the plurality of connection lines 50 on the basis of the detection voltage generated at the drain of each transistor 24. As the above-described determination process, the determination circuit 30 may output information indicating a connection line that is disconnected among the plurality of connection lines 50.

Hereinafter, an aspect of detecting disconnection of the connection line 50 in the battery monitoring device 10 will be described. In the following description, a case will be exemplified in which disconnection occurs in the connection line 50₂ and no disconnection occurs in the connection lines 50 other than the connection line 50₂. In a case where disconnection occurs in the connection line 50₂, a potential of the positive electrode of the battery cell 40₂ is not applied to the internal wiring 21₂ connected to the connection line 50₂, and the connection line 50₂ has substantially the same potential as a potential of the connection line 50₁. Therefore, the transistor 24₂ is turned off, and a low-level detection voltage indicating that disconnection has occurred in the connection line 50₂ is output from the drain of the transistor 24₂.

On the other hand, in each of the internal wirings 21 connected to the connection lines 50 other than the connection line 50₂, a potential difference corresponding to the cell voltage is generated between the internal wirings 21 adjacent to each other. As a result, each of the P-channel type transistors 24 other than the transistor 24₂ is turned on, and a high-level detection voltage indicating that no disconnection occurs in the corresponding connection line 50 is output from the drain of each of the transistors 24. On the other hand, the N-channel transistor 24₀ is turned off, and a high-level detection voltage indicating that no disconnection occurs in the corresponding connection line 50₀ is output from the drain of the transistor 24₀.

The detection voltages generated at the respective drains of the transistors 24 are simultaneously input to the determination circuit 30. The determination circuit 30 determines that disconnection has occurred in the connection line 50₂ and that no disconnection occurs in the connection lines 50 other than the connection line 50₂, on the basis of the detection voltages generated at the respective drains of the transistors 24. The determination circuit 30 outputs information indicating that disconnection has occurred in the connection line 50₂.

In the above description, the aspect of detecting disconnection of the connection line 50₂ has been exemplified, but an aspect of detecting disconnection of the connection line 50₀ is as follows. In a case where no disconnection occurs in the connection line 50₀, the internal wiring 21₀ connected to the connection line 50₀ has the same potential as a potential of the ground wiring 23 (that is, the ground potential). As a result, the transistor 24₀ is turned off, and a high-level detection voltage indicating that no disconnection occurs in the corresponding connection line 50₀ is output from the drain of the transistor 24₀. On the other hand, in a case where disconnection has occurred in the connection line 50₀, the internal wiring 21₀ is biased by the current source 26. As a result, the transistor 24₀ is turned on, and a low-level detection voltage indicating that disconnection has occurred in the corresponding connection line 50₀ is output from the drain of the transistor 24₀.

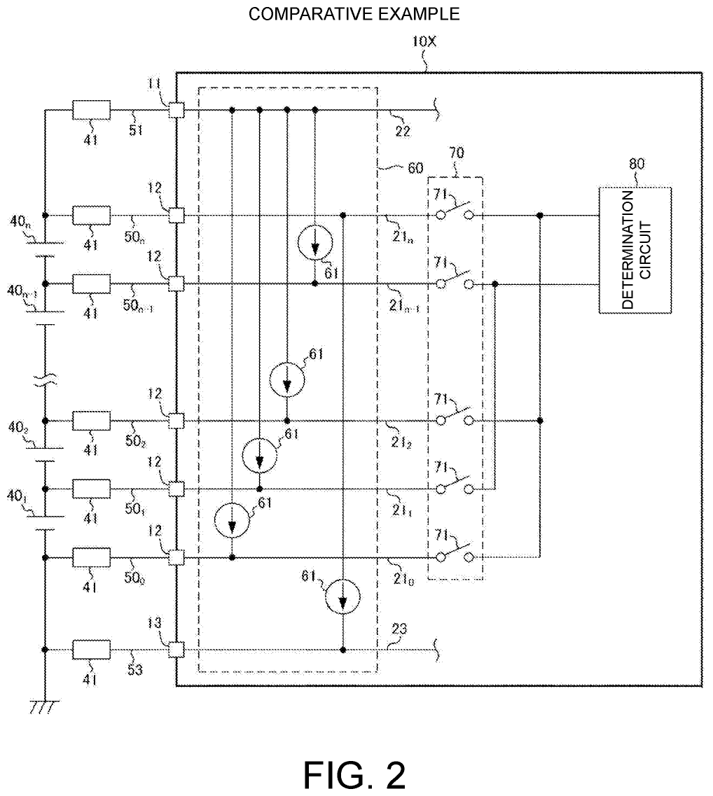

FIG. 2 is a diagram illustrating an example of a configuration of a battery monitoring device 10X according to a comparative example. FIG. 2 illustrates functional portions related to disconnection detection for the connection line 50 in the battery monitoring device 10X. The battery monitoring device 10X according to the comparative example includes a current source circuit 60, a cell selection circuit 70, and a determination circuit 80. The cell selection circuit 70 has a plurality of switches 71 provided to correspond to the plurality of connection lines 50. Each of the switches 71 has one end connected to the corresponding connection line 50 via the internal wiring 21 and the other end connected to the determination circuit 30. The current source circuit 60 has a plurality of current sources 61 respectively connected to the internal wirings 21.

In the battery monitoring device 10X according to the comparative example, one of the plurality of battery cells 40 is selected by selectively turning on one of the plurality of switches 71 configuring the cell selection circuit 70. The selected battery cell 40 is connected to the determination circuit 80 via the connection line 50, the internal wiring 21, and the switch 71 that is turned on, and a cell voltage of the battery cell 40 is measured by the determination circuit 80. For the battery cell 40 that is a measurement target, the determination circuit 80 determines the presence or absence of disconnection of the corresponding connection line 50 on the basis of a difference between a cell voltage when the current source 61 is turned on and a cell voltage when the current source 61 is turned off.

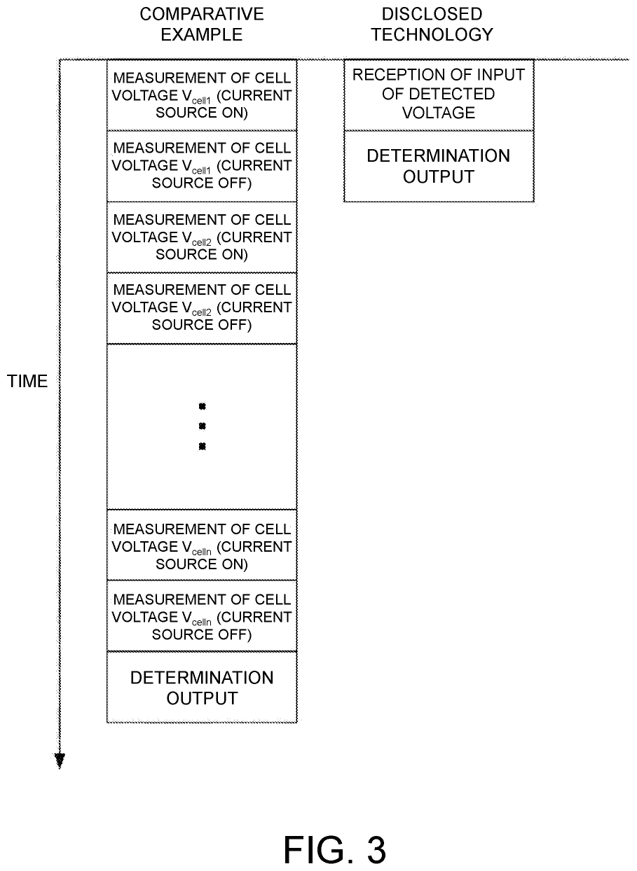

The left side of FIG. 3 illustrates a flow of each process performed when the determination circuit 80 of the battery monitoring device 10X according to the comparative example detects disconnection of the connection line 50. First, the determination circuit 80 according to the comparative example measures a cell voltage V_{cell1} of the battery cell 40₁ when the current source 61 is turned on. Next, the determination circuit 80 measures the cell voltage V_{cell1} of the battery cell 40₁ when the current source 61 is turned off. Next, the determination circuit 80 measures a cell voltage V_{cell2} of the battery cell 40₂ when the current source 61 is turned on. Next, the determination circuit 80 measures the cell voltage V_{cell2} of the battery cell 40₂ when the current source 61 is turned off. Similarly, the determination circuit 80 sequentially measures a cell voltage when the current source 61 is turned on and a cell voltage when the current source 61 is turned off for all the battery cells 40. The determination circuit 80 outputs a determination result of the presence or absence of disconnection of each connection line 50 on the basis of a difference between the cell voltage when the current source 61 is turned on and the cell voltage when the current source 61 is turned off.

The right side of FIG. 3 illustrates a flow of each process performed when the determination circuit 30 of the battery monitoring device 10 according to the embodiment of the disclosed technology detects disconnection of the connection line 50. First, the determination circuit 30 of the battery monitoring device 10 collectively receives input of the detection voltages generated at the respective drains of the transistors 24. Next, the determination circuit 30 outputs a determination result of the presence or absence of disconnection of each connection line 50 on the basis of the detection voltage. As is clear from FIG. 3, according to the battery monitoring device 10 of the embodiment of the disclosed technology, the time required to detect disconnection of the connection line 50 can be significantly reduced compared with the battery monitoring device 10X according to the comparative example.

As described above, the battery monitoring device 10 according to the embodiment of the disclosed technology has a function of detecting disconnection of each of the plurality of connection lines 50 respectively connected to the battery cells 40 of the battery pack in which the plurality of battery cells 40 is connected in series. The battery monitoring device 10 includes the plurality of internal wirings 21 respectively connected to the plurality of connection lines 50, the plurality of transistors 24 that is provided to correspond to the plurality of internal wirings 21 and is turned on according to a potential difference between the corresponding internal wiring 21 and the internal wiring 21 adjacent thereto, and the determination circuit 30 that performs a determination process of determining the presence or absence of disconnection of each of the plurality of connection lines 50 on the basis of output voltages of the plurality of transistors 24.

According to the battery monitoring device 10 of the embodiment of the disclosed technology, the output voltages of the plurality of transistors 24 are simultaneously input to the determination circuit 30 as detection voltages indicating the presence or absence of disconnection of the plurality of respective connection lines 50. The determination circuit 30 performs the above determination process on the basis of the detection voltages. Therefore, according to the battery monitoring device 10 of the embodiment of the disclosed technology, it is possible to detect disconnection of a plurality of connection lines in a short time.

Regarding the above embodiments, the following Supplementary Notes are further disclosed.

### (Supplementary Note 1)

A battery monitoring device having a function of detecting disconnection of each of a plurality of connection lines respectively connected to a plurality of battery cells of a battery pack in which the plurality of battery cells is connected in series, the battery monitoring device including:
a plurality of internal wirings respectively connected to the plurality of connection lines;
a plurality of transistors provided to correspond to the plurality of internal wirings and turned on according to a potential difference between a corresponding internal wiring and an internal wiring adjacent to the corresponding internal wiring; and
a determination circuit that performs a determination process of determining presence or absence of disconnection of each of the plurality of connection lines based on output voltages of the plurality of transistors.

### (Supplementary Note 2)

The battery monitoring device according to Supplementary Note 1, in which
the plurality of transistors includes P-channel transistors each having a source connected to a corresponding internal wiring, a gate connected to an adjacent internal wiring on a low potential side, and a drain connected to a first current source, and
voltages generated at the respective drains of the P-channel transistors are input to the determination circuit as the output voltages.

### (Supplementary Note 3)

The battery monitoring device according to Supplementary Note 1 or 2, further including:
a lowest potential internal wiring that is an internal wiring connected to a lowest potential connection line and to which a ground potential is applied when the lowest potential connection line is not disconnected;
a second current source that biases the lowest potential internal wiring; and
an N-channel transistor having a gate connected to the lowest potential internal wiring, a source connected to a ground wiring to which the ground potential is applied, and a drain connected to a third current source, in which
a voltage generated at the drain of the N-channel transistor is input to the determination circuit as the output voltage.

### (Supplementary Note 4)

The battery monitoring device according to any one of Supplementary Notes 1 to 3, in which the output voltages of the plurality of transistors are simultaneously input to the determination circuit.

### (Supplementary Note 5)

The battery monitoring device according to any one of Supplementary Notes 1 to 4, in which the determination circuit outputs information indicating a connection line in which disconnection occurs among the plurality of connection lines.

What is claimed is:

1. A battery monitoring device having a function of detecting disconnection of each of a plurality of connection lines respectively connected to a plurality of battery cells of a battery pack in which the plurality of battery cells is connected in series, the battery monitoring device comprising:
a plurality of internal wirings respectively connected to the plurality of connection lines;
a plurality of transistors provided to correspond to the plurality of internal wirings and turned on according to a potential difference between a corresponding internal wiring and an internal wiring adjacent to the corresponding internal wiring; and
a determination circuit that performs a determination process of determining presence or absence of disconnection of each of the plurality of connection lines based on output voltages of the plurality of transistors.

2. The battery monitoring device according to claim 1, wherein
the plurality of transistors includes P-channel transistors each having a source connected to a corresponding internal wiring, a gate connected to an adjacent internal wiring on a low potential side, and a drain connected to a first current source, and
voltages generated at the respective drains of the P-channel transistors are input to the determination circuit as the output voltages.

3. The battery monitoring device according to claim 1, further comprising:
a lowest potential internal wiring that is an internal wiring connected to a lowest potential connection line and to which a ground potential is applied when the lowest potential connection line is not disconnected;
a second current source that biases the lowest potential internal wiring; and
an N-channel transistor having a gate connected to the lowest potential internal wiring, a source connected to a ground wiring to which the ground potential is applied, and a drain connected to a third current source, wherein
a voltage generated at the drain of the N-channel transistor is input to the determination circuit as the output voltage.

4. The battery monitoring device according to claim 1, wherein
the output voltages of the plurality of transistors are simultaneously input to the determination circuit.

5. The battery monitoring device according to claim 1, wherein
the determination circuit outputs information indicating a connection line in which disconnection occurs among the plurality of connection lines.
